(19) United States
(12) Patent Application Publication
(10) Pub. No.: US 2015/0115293 A1
(43) Pub. Date: Apr. 30, 2015

(54) LIGHT EMITTING DIODE DISPLAY PANEL

(71) Applicant: AU Optronics Corp., Hsin-Chu (TW)

(72) Inventors: Tsung-Tien Wu, Hsin-Chu (TW); Kang-Hung Liu, Hsin-Chu (TW); Jiun-Jye Chang, Hsin-Chu (TW); Min-Feng Chiang, Hsin-Chu (TW)

(21) Appl. No.: 14/302,430

(22) Filed: Jun. 12, 2014

(30) Foreign Application Priority Data
Oct. 30, 2013 (TW) 102139389

(51) Int. Cl. H01L 27/15; H01L 33/00

(52) U.S. Cl. CPC H01L 27/153; H01L 33/005; H01L 2933/0016
USPC 257/88; 438/28

(57) ABSTRACT

A light emitting diode (LED) display panel and fabrication method thereof are provided. The LED display panel includes a plurality of dielectric patterns and LED devices, and the dielectric patterns are formed on a substrate subsequent to formation of the LED devices. The dielectric pattern surrounds sidewalls of the corresponding LED device, and exposes an electrode of the LED device. The upper surface of the dielectric pattern and the electrode of the LED device are located at the same level approximately, and a connection electrode is disposed on the dielectric pattern, and electrically connected to the electrode of the LED device and a signal line.

### BACKGROUND OF THE INVENTION

1. Field of the Invention

The present invention relates to a display panel and method of fabricating the same, and more particularly, to a light emitting diode (LED) display panel and method of fabricating the same.

2. Description of the Prior Art

Light emitting diode (LED) display panel is a display panel having a pixel array composed of LED devices. The LED device is advantageous for its high luminance and low power consumption, and thus is widely adopted in illumination applications. However, the light uniformity, yield and reliability of LED display panel are not satisfactory, and thus the LED display panel is merely used in low-end display application, for example outdoor advertising billboard.

### SUMMARY OF THE INVENTION

It is therefore one of the objectives of the present invention to provide a display panel and method of fabricating the same to increase light uniformity, yield and reliability.

According to an embodiment of the present invention, a light emitting diode (LED) display panel is provided. The LED display panel includes a substrate, a plurality of driving devices, an insulating layer, a plurality of first connection electrodes, a plurality of LED devices, a plurality of dielectric patterns, a plurality of signal lines and a plurality of second connection electrodes. The substrate has a plurality of sub-pixel regions, and at least one driving device is disposed in each of the sub-pixel regions. The insulating layer is disposed on the substrate and covers the driving devices, wherein the insulating layer has a plurality of openings partially exposing the driving devices respectively. The first connection electrodes are disposed on the insulating layer, wherein the first connection electrodes are electrically connected to the driving devices through the openings respectively. The LED devices are disposed on the substrate, wherein at least one of the LED devices is disposed in each of the sub-pixel regions. Each of the LED devices includes a first electrode, a second electrode and a light emitting layer interposed between the first electrode and the second electrode, and the first electrodes are disposed on and electrically connected to the first connection electrodes respectively. The dielectric patterns are disposed on the first connection electrodes respectively, wherein each of the dielectric patterns surrounds a sidewall of the corresponding LED device and exposes the second electrode of the corresponding LED device. The signal lines are disposed on the substrate, wherein each of the signal lines is disposed on one side of the corresponding sub-pixel regions. The second connection electrodes are disposed on the dielectric patterns respectively, wherein the second connection electrodes are disposed in the sub-pixel regions respectively, and each of the second connection electrodes is electrically connected to the second electrode of the LED device exposed by the corresponding dielectric pattern and the corresponding signal line.

According to another embodiment of the present invention, a method of fabricating light emitting diode (LED) display panel is provided. The method of fabricating LED display panel includes the following steps. A substrate having a plurality of sub-pixel regions is provided. A plurality of driving devices are formed on the substrate, wherein at least one of the driving devices is disposed in each of the sub-pixel regions. An insulating layer is formed on the substrate and the driving devices, wherein the insulating layer has a plurality of openings partially exposing the driving devices respectively. A plurality of first connection electrodes are formed on the insulating layer and in the sub-pixel regions respectively, wherein the first connection electrodes are electrically connected to the driving devices through the openings respectively. At least one LED device and a dielectric pattern are formed on each of the first connection electrodes, wherein each of the LED devices comprises a first electrode, a second electrode and a light emitting layer interposed between the first electrode and the second electrode, and each of the first electrodes is disposed on and electrically connected to the corresponding first connection electrode, and each of the dielectric patterns surrounds a sidewall of the corresponding LED device and exposes the second electrode of the corresponding LED device. A plurality of signal lines are formed on the substrate, wherein each of the signal lines is disposed on one side of the corresponding sub-pixel regions. A plurality of second connection electrodes are formed on the dielectric patterns respectively, wherein each of the second connection electrodes is electrically connected to the second electrode of the LED device exposed by the corresponding dielectric pattern and the corresponding signal line.

According to the method of fabricating LED display panel of the present invention, the LED devices are first formed on the substrate, and then the dielectric patterns are subsequently formed to surround the sidewalls of the LED devices. Consequently, the LED devices are well protected by the dielectric patterns. In addition, since the top surface of the dielectric pattern and the second electrode of the LED device are disposed at the same horizontal level or the height gap between the top surface of the dielectric pattern and the second electrode is small, the line broken risk of the second connection electrode is reduced. Moreover, the dielectric pattern has light diffuse effect, which can effectively increase light uniformity.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 are schematic diagrams illustrating a method of fabricating an LED display panel according to a first embodiment of the present invention.

FIG. 8 is a schematic diagram illustrating an LED display panel according to an alternative embodiment of the first embodiment of the present invention.

FIG. 9 and FIG. 10 are schematic diagrams illustrating an LED display panel according to a second embodiment of the present invention.

FIG. 11 is a schematic diagram illustrating an LED display panel according to an alternative embodiment of the second embodiment of the present invention.

FIGS. 12-16 are schematic diagrams illustrating a method of fabricating an LED display panel according to a third embodiment of the present invention.

FIG. 17 is a schematic diagram illustrating an LED display panel according to an alternative embodiment of the third embodiment of the present invention.

### DETAILED DESCRIPTION

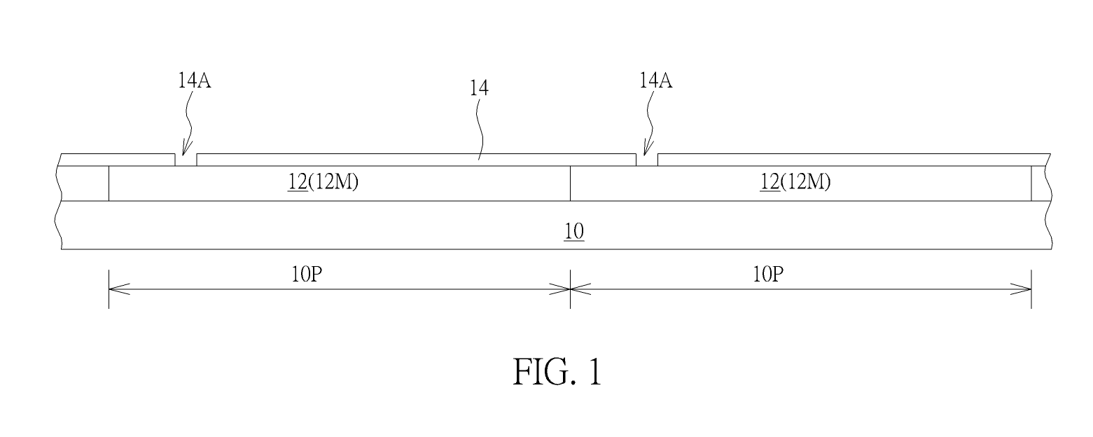

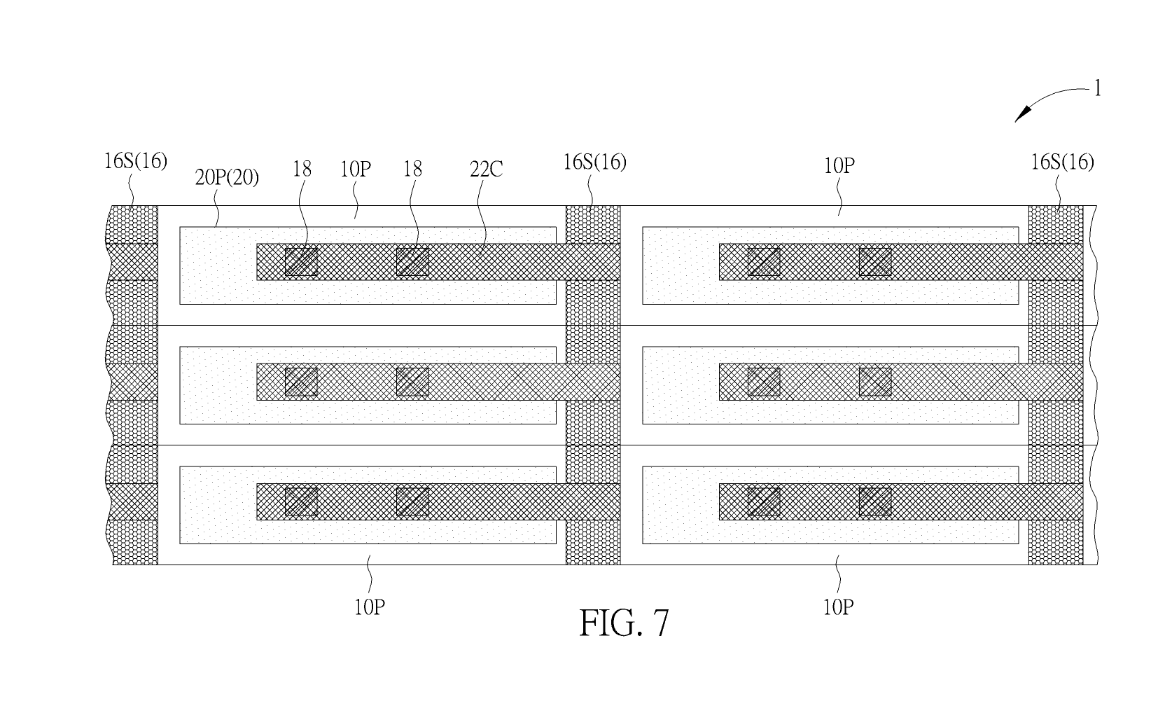

Refer to FIGS. 1-7. FIGS. 1-7 are schematic diagrams illustrating a method of fabricating an LED display panel according to a first embodiment of the present invention, where FIGS. 1-6 are cross-sectional views and FIG. 7 is a top view. As shown in FIG. 1, a substrate 10 is provided. The substrate 10 may be a rigid substrate or a flexible substrate e.g. a glass substrate, a quartz substrate, a plastic substrate or any other suitable substrate. The substrate 10 has a plurality of sub-pixel regions 10P arranged in an array form. Then, a driving device array 12M is formed on the substrate 10. The driving device array 12M includes a plurality of driving devices 12, wherein at least one driving device 12 and other devices that can realize driving function e.g. a capacitor device (not shown) are disposed in each of the sub-pixel regions 10P. In this embodiment, the number of the driving device 12, the capacitor device or other devices in each sub-pixel region 10P may be modified based on the driving architecture of the LED display panel. For example, the driving architecture of the LED display panel may be 2T1C (2 transistors and 1 capacitor) architecture, 3T1C architecture, 4T2C architecture, 2T2C architecture, 5T1C architecture, 6T1C architecture or other driving architectures. In addition, other conductive lines for driving the driving devices 12 e.g. gate lines, data lines and power lines may be formed in the sub-pixel regions 10P. The function and arrangement of the aforementioned conductive lines are well known, and thus are not redundantly described. Subsequently, an insulating layer 14 is formed on the substrate 10 and the driving devices 12. The insulating layer 14 has a plurality of openings 14A, partially exposing the driving devices 12, respectively. The insulating layer 14 may be a single-layered structure or a multi-layered structure, and the material of the insulating layer 14 may include inorganic material, organic material or organic/inorganic hybrid material.

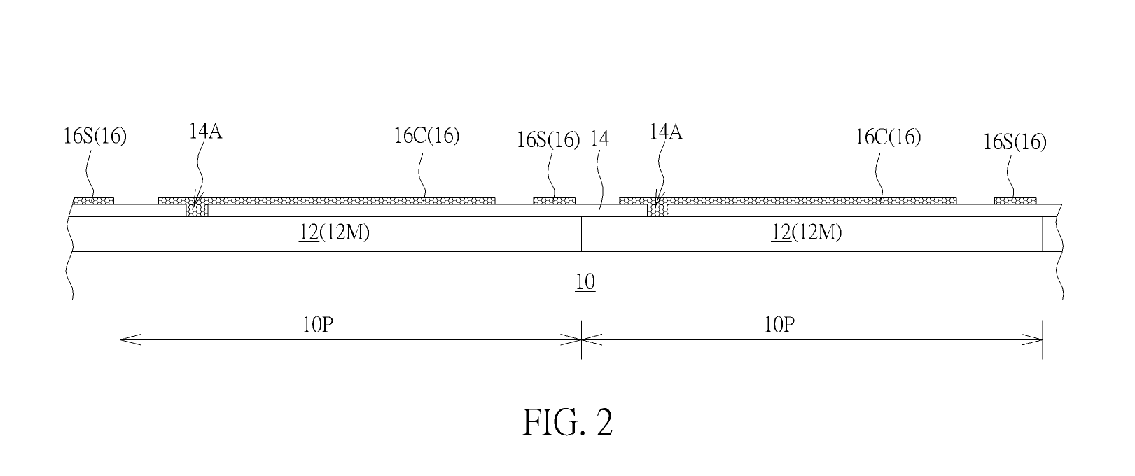

As shown in FIG. 2, a patterned conductive layer 16 is formed on the insulating layer 14. The patterned conductive layer 16 includes a plurality of first connection electrodes 16C disposed in the sub-pixel regions 10P respectively, and each first connection electrode 16C is electrically connected to the corresponding driving device 12 through the opening 14A of the insulating layer 14. The first connection electrode 16C may be a single-layered electrode structure such as a non-transparent connection electrode (e.g. metal electrode) or a transparent connection electrode (e.g. indium tin oxide (ITO) electrode). Alternatively, the first connection electrode 16C may be a multi-layered electrode structure such as a stacking structure of a non-transparent connection electrode (e.g. metal electrode) and a transparent connection electrode (e.g. ITO electrode). In addition, a welding layer (not shown) maybe optionally formed on the surface of the first connection electrode 16C to bond an LED device to be formed. The welding layer may fully cover the upper surface of the first connection electrode 16C, or may merely partially cover the upper surface of the first connection electrode 16C and corresponding to the location of the LED device to be formed. The material of the welding layer may be low temperature welding material such as indium (In) or other conductive materials with good conductivity e.g. metal, non-metal, alloy or an oxide compound thereof. In addition, the patterned conductive layer 16 may further include a plurality of signal lines 16S disposed on the insulating layer 14, and each signal line 16S is disposed on one side of the corresponding sub-pixel regions 10P. For example, each signal line 16S may be disposed on one side of the sub-pixel regions 10P of one corresponding column, but not limited thereto.

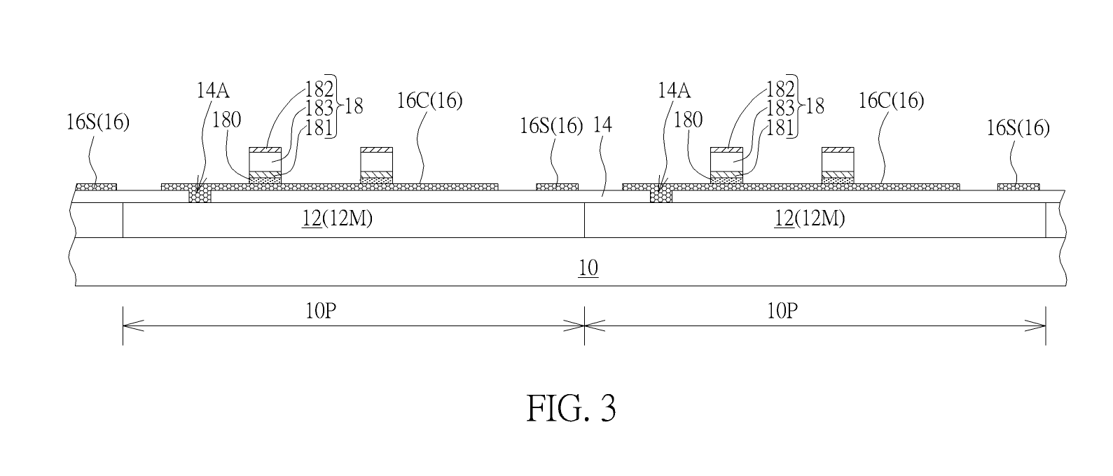

As shown in FIG. 3, at least one LED device 18 is formed on each first connection electrode 16C. In this embodiment, there are two LED devices 18 in each sub-pixel region 10P, but not limited thereto. The number and arrangement density may be modified based on the brightness requirement, the dimension specification of the sub-pixel region 10P and the dimension specification of the LED device 18. For example, there may be only one LED device 18 in each sub-pixel region 10P or more than two LED devices 18 in each sub-pixel region 10P. Each LED device 18 includes a first electrode (bottom electrode) 181, a second electrode (top electrode) 182 and a light emitting layer 183 interposed between the first electrode 181 and the second electrode 182, and each first electrode 181 is disposed on and electrically connected to the corresponding first connection electrode 16C. In this embodiment, the first electrode 181 is an anode, and the second electrode 182 is a cathode, but not limited thereto. The light emitting layer 183 is an inorganic light emitting layer, which can radiate light when driven by the voltage difference between the first electrode 181 and the second electrode 182. In this embodiment, the LED device 18 is fabricated in advance, and then mounted on and electrically connected to the first connection electrode 16C. Specifically, the first electrode 181, the light emitting layer 183 and the second electrode 182 are not sequentially formed on the first connection electrode 16C by thin film processes. For example, each LED device 18 may be picked up and placed on the corresponding first connection electrode 16C by a micro mechanical apparatus, and a conductive adhesive material 180 e.g. indium (In) may be used to weld the first LED device 18 on the first connection electrode 16C. The first electrode 181 is therefore electrically connected to the first connection electrode 16C through the conductive adhesive material 180. In another embodiment, the LED device 18 may be directly or indirectly mounted on the first connection electrode 16C in another manner. For example, when a welding layer is formed on the upper surface of the first connection electrode 16C, the LED device is mounted on the welding layer by the conductive adhesive material 180.

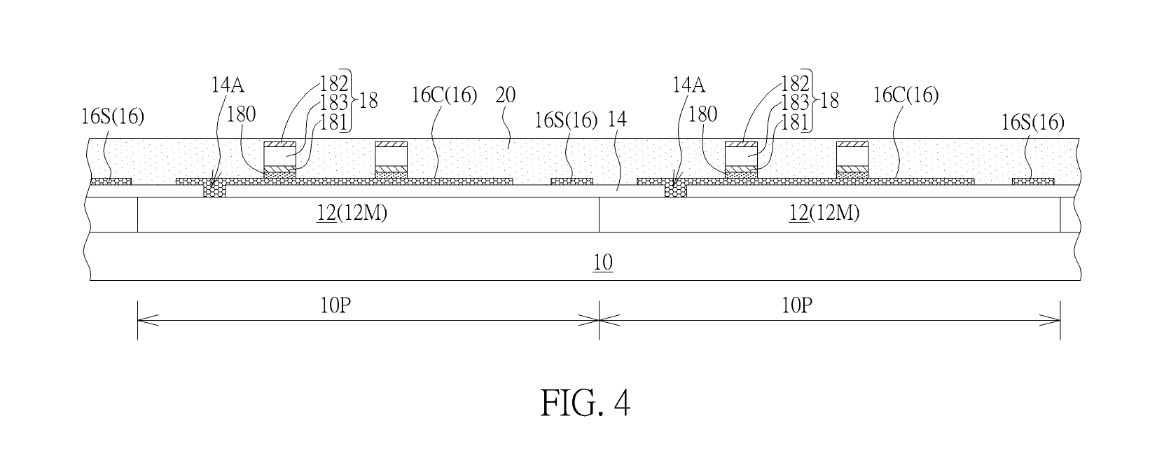

As shown in FIG. 4, a dielectric material layer 20 is then formed to cover the first connection electrodes 16C and the LED devices 18. The dielectric material layer 20 covers the sidewall and the second electrode 182 of each LED device 18. The material of the dielectric material layer 20 may include inorganic material, organic material or organic/inorganic hybrid material with high transparency. In this embodiment, the material of the dielectric material layer 20 is preferably a photo-sensitive material e.g. photoresist material, but not limited thereto.

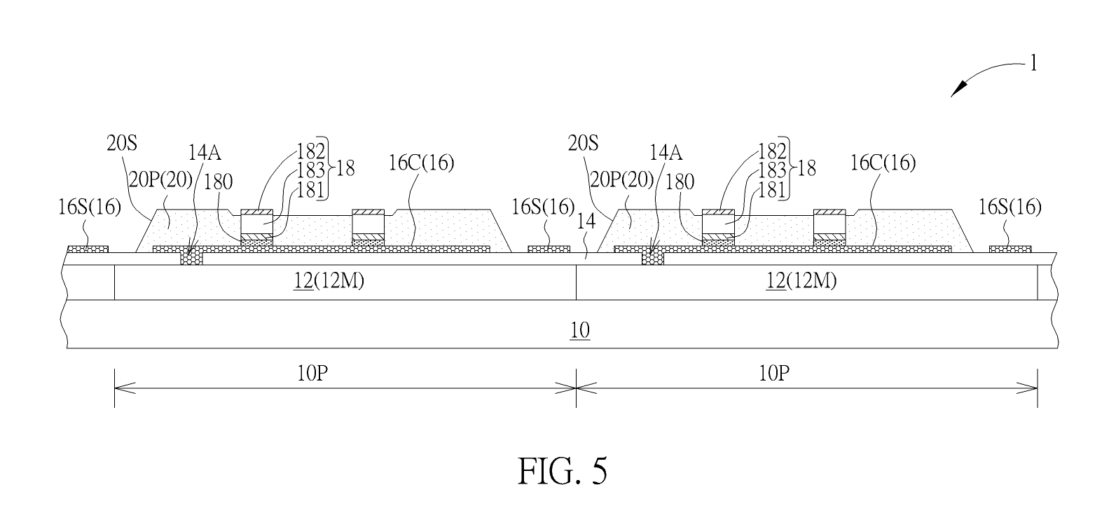

As shown in FIG. 5, the dielectric material layer 20 is then patterned to form a dielectric pattern 20P on each first connection electrode 16C. The dielectric pattern 20P surrounds the sidewall of the corresponding LED device 18, and exposes the second electrode 182 of the LED device 18 and the signal line 16S for successive electrical connection purpose. In this embodiment, the material of the dielectric material layer 20 is selected from photo-sensitive materials, so that the dielectric material layer 20 can be patterned by exposure and development processes with a photomask to form the dielectric patterns 20P. The photomask is preferably a graytone photomask, so that the dielectric pattern 20P may expose the second electrode 182 and the signal line 16S and the dielectric pattern 20P may have an inclined sidewall 20S, which prevents a second connection electrode to be formed from breaking and increases illumination efficiency. In addition, the top surface of the dielectric pattern 20P and the second electrode 182 are preferably located at the same horizontal level approximately or the height gap between the top surface of the dielectric pattern 20P and the second electrode 182 is as small as possible. In an alternatively, the dielectric patterns 20P may be formed by another patterning process e.g. an etching process . The sidewall of the LED device 18 is surrounded by the dielectric pattern 20P, and thus the LED device 18 is well protected. In addition, the dielectric pattern 20P has light diffuse effect, which can increase light uniformity. The light diffuse effect of the dielectric pattern 20P is significant, particularly when only one single LED device 18 is formed in each sub-pixel region 10P.

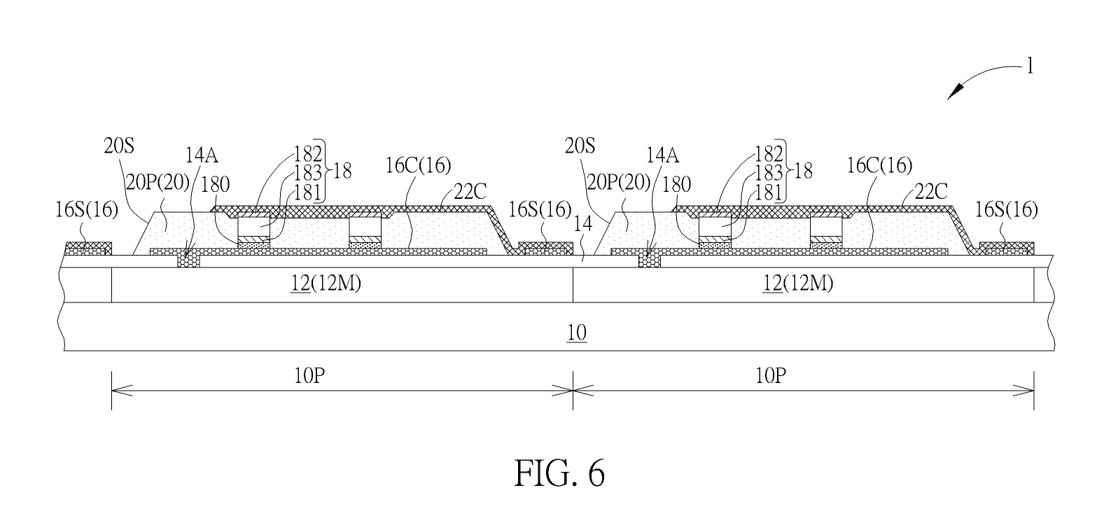

As shown in FIG. 6 and FIG. 7, a second connection electrode 22C is formed on each dielectric pattern 20P. Each second connection electrode 22C is electrically connected to the second electrode 182 of the LED device 18 exposed by the corresponding dielectric pattern 20P and the corresponding signal line 16S to from an LED display panel 1 of this embodiment. The second connection electrode 22C may be a single-layered electrode structure such as a non-transparent connection electrode (e.g. metal electrode) or a transparent connection electrode (e.g. indium tin oxide (ITO) electrode). Alternatively, the second connection electrode 22C may be a multi-layered electrode structure such as a stacking structure of a non-transparent connection electrode (e.g. metal electrode) and a transparent connection electrode (e.g. ITO electrode). The second connection electrodes 22C may be formed on the dielectric patterns 20P by thin film deposition process, an inkjet printing process, a screen printing process or other suitable processes. Since the top surface of the dielectric pattern 20P and the second electrode 182 are located at the same horizontal level approximately or the height gap between the top surface of the dielectric pattern 20P and the second electrode 182 is small, the line broken risk of the second connection electrode 22C due to large height gap is reduced, and thus the yield and reliability of the LED display device 1 is increased.

The LED display panel and method of fabricating the same are not limited by the aforementioned embodiment, and may have other different preferred embodiments. To simplify the description, the identical components in each of the following embodiments are marked with identical symbols. For making it easier to compare the difference between the embodiments, the following description will detail the dissimilarities among different embodiments and the identical features will not be redundantly described.

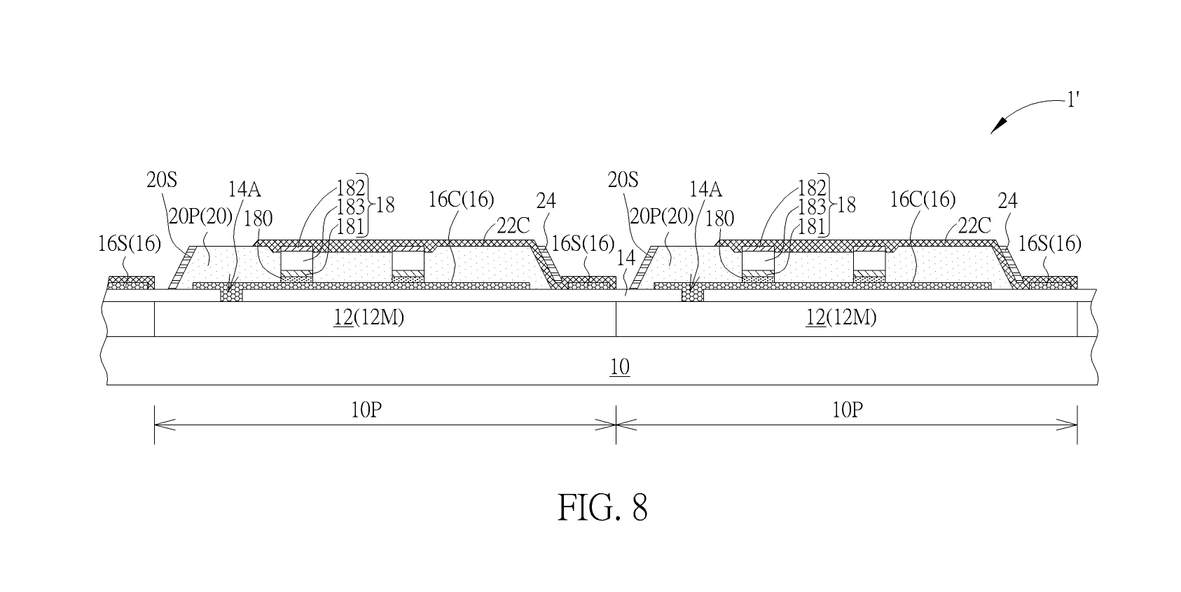

Refer to FIG. 8. FIG. 8 is a schematic diagram illustrating an LED display panel according to an alternative embodiment of the first embodiment of the present invention. As shown in FIG. 8, different from the first embodiment, the method of fabricating the LED display panel in this alternative embodiment further includes forming a reflection pattern 24 on the inclined sidewall 20S of each dielectric pattern 20P. The material of the reflection pattern 24 may include metal or other materials with reflective characteristics. The LED display panel 1′ of this alternative embodiment includes the reflection patterns 24, which can increase reflection and light collection effects, and thus the amount of outgoing light and the uniformity of light can be enhanced.

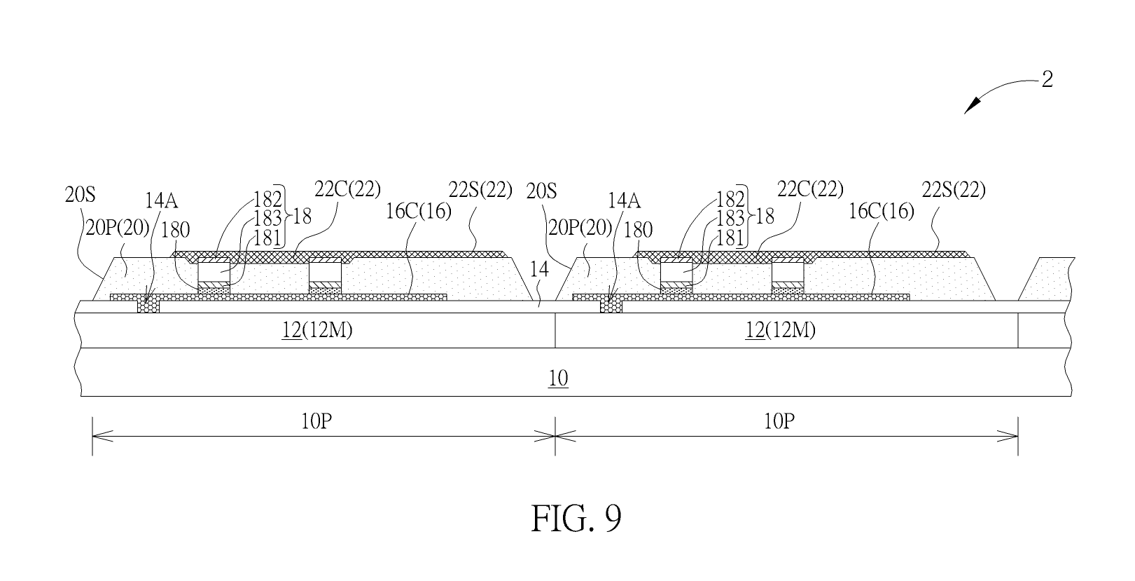

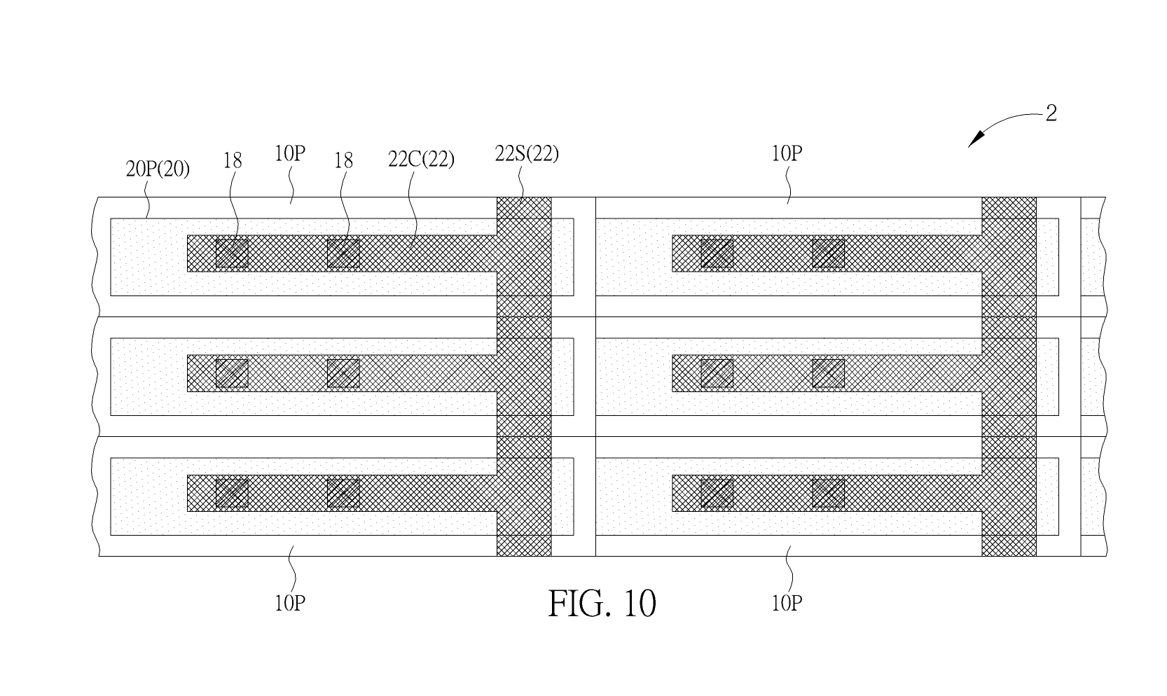

Refer to FIG. 9 and FIG. 10. FIG. 9 and FIG. 10 are schematic diagrams illustrating an LED display panel according to a second embodiment of the present invention, where FIG. 9 is a cross-sectional view and FIG. 10 is a top view. As shown in FIG. 9 and FIG. 10, different from the first embodiment, in an LED display panel 2 of the second embodiment, the signal lines 22S are not made of the patterned conductive layer 16, but made of another patterned conductive layer 22 along with the second connection electrodes 22C. Specifically, the signal lines 22S and the second connection electrodes 22C are made of the same patterned conductive layer 22. Accordingly, the signal lines 22S are disposed on the dielectric patterns 20P, and the signal lines 22S and the second connection electrodes 22C are located at the same horizontal level approximately.

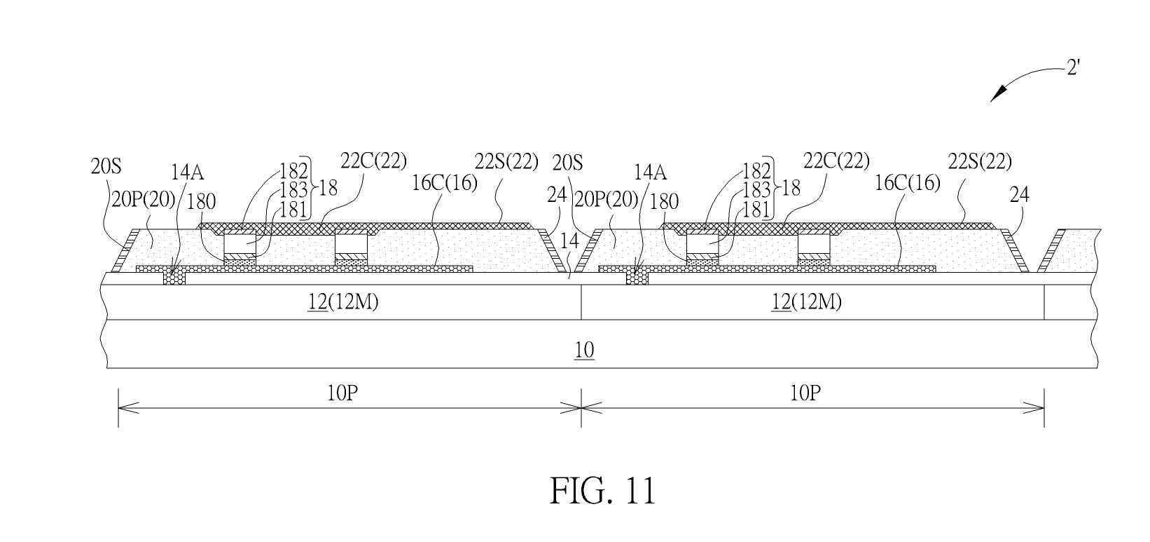

Refer to FIG. 11. FIG. 11 is a schematic diagram illustrating an LED display panel according to an alternative embodiment of the second embodiment of the present invention. As shown in FIG. 11, different from the second embodiment, the method of fabricating the LED display panel in this alternative embodiment further includes forming a reflection pattern 24 on the inclined sidewall 20S of each dielectric pattern 20P. The material of the reflection pattern 24 may include metal or other materials with reflective characteristics. The LED display panel 2′ of this alternative embodiment includes the reflection patterns 24, which can increase reflection and light collection effects, and thus the amount of outgoing light and the uniformity of light can be enhanced.

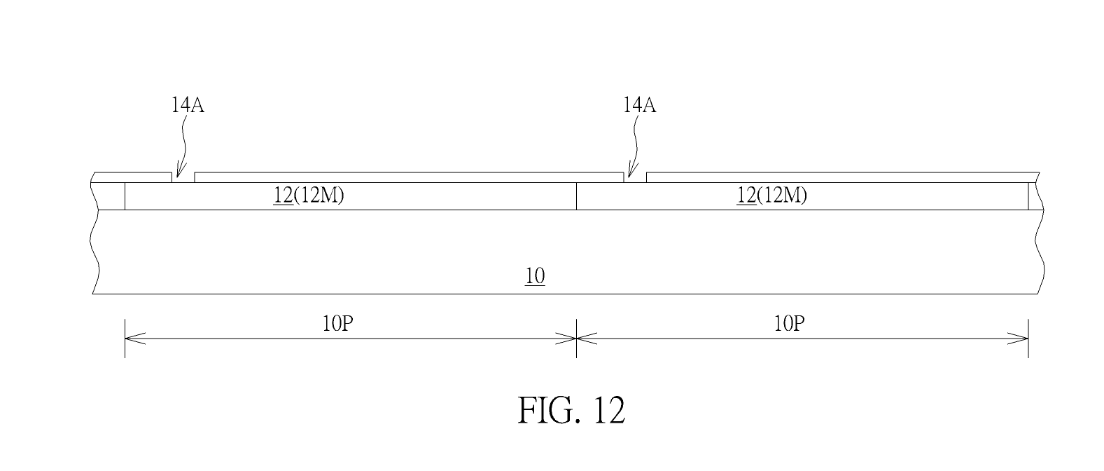

Refer to FIGS. 12-16. FIGS. 12-16 are schematic diagrams illustrating a method of fabricating an LED display panel according to a third embodiment of the present invention. As shown in FIG. 12, a substrate 10 is provided. The substrate 10 has a plurality of sub-pixel regions 10P arranged in an array form. Then, a driving device array 12M is formed on the substrate 10. The driving device array 12M includes a plurality of driving devices 12, wherein at least one driving device 12 is disposed in each of the sub-pixel regions 10P. Subsequently, an insulating layer 14 is formed on the substrate 10 and the driving devices 12. The insulating layer 14 has a plurality of openings 14A, partially exposing the driving devices 12, respectively. The insulating layer 14 may be a single-layered structure or a multi-layered structure, and the material of the insulating layer 14 may include inorganic material, organic material or organic/inorganic hybrid material.

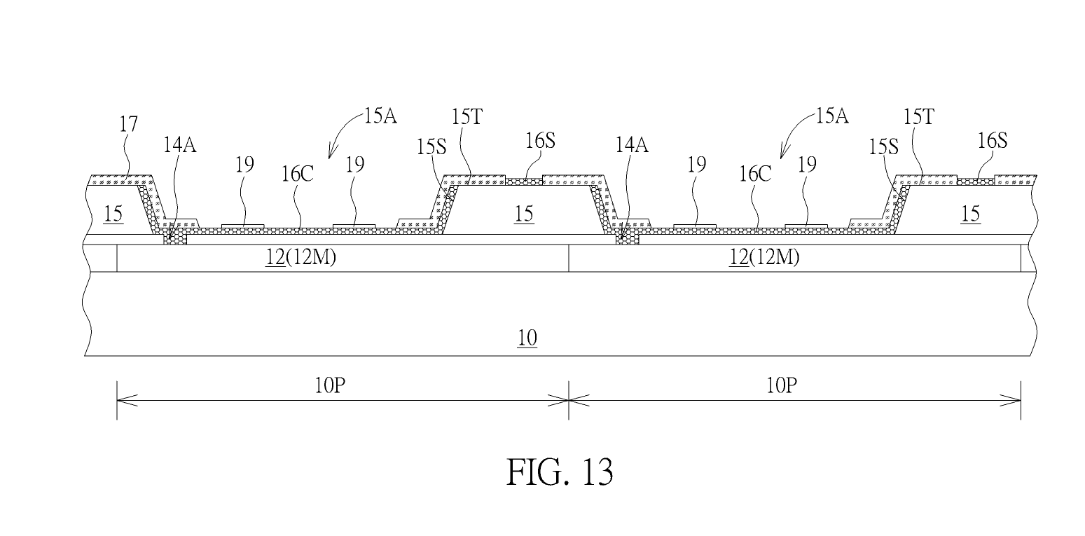

As shown in FIG. 13, a patterned bank 15 is formed on the insulating layer 14 . The patterned bank 15 has a plurality of cavities 15A defining the sub-pixel regions 10P, respectively. The material of the patterned bank 15 may be selected from photo-sensitive materials e.g. photoresist, so that the patterned bank 15 can be formed by exposure and development processes with a photomask. The cavity 15A of the patterned bank 15 preferably has an inclined sidewall 15S. Then, a patterned conductive layer 16 is formed on the insulating layer 14. The patterned conductive layer 16 includes a plurality of first connection electrodes 16C disposed in the cavities 15A in the sub-pixel regions lop, respectively, and each first connection electrode 16 is electrically connected to the corresponding driving device 12 through the corresponding opening 14A of the insulating layer 14. The first connection electrode 16C maybe a single-layered electrode structure such as a non-transparent connection electrode (e.g. metal electrode) or a transparent connection electrode (e.g. indium tin oxide (ITO) electrode). Alternatively, the first connection electrode 16C may be a multi-layered electrode structure such as a stacking structure of a non-transparent connection electrode (e.g. metal electrode) and a transparent connection electrode (e.g. ITO electrode). In addition, a welding layer 19 may be optionally formed on the surface of the first connection electrode 16C to bond an LED device to be formed. The material of the welding layer 19 is preferably a low temperature welding material such as indium (In), but not limited thereto. The material of the welding layer 19 may also be other conductive materials with good conductivity e.g. metal, non-metal, alloy or an oxide compound thereof. In this embodiment, the dimension of the welding layer 19 and the dimension of the LED device to be formed are substantially equal and corresponsive, but not limited. For example, the pattern of the welding layer 19 and the pattern of the first connection electrode 16C may be corresponsive, and may be defined by the same patterning process. Furthermore, the first connection electrode 16C may optionally covers the inclined sidewall 15S of the cavity 15A of the patterned bank 15 as a reflection pattern to increase reflection and light collection effects, thereby increasing the amount of outgoing light and light uniformity. Alternatively, the reflection patterned may be formed by an additional layer. The patterned conductive layer 16 may further includes a plurality of signal lines 16S disposed on the patterned bank 15, and each signal line 16S is disposed on one side of the corresponding sub-pixel regions 10P. For example, each signal line 16S may be disposed on one side of the sub-pixel regions 10P of one corresponding column, but not limited thereto. In addition, a passivation layer 17 may be optionally formed on the top surface 15T and the inclined sidewall 15S of the patterned bank 15. The passivation layer 17 partially covers the first connection electrodes 16C and exposes the signal lines 16S. The passivation layer 17 is able to prevent short-circuitry between the first connection electrodes 16C and the second connection electrodes to be formed.

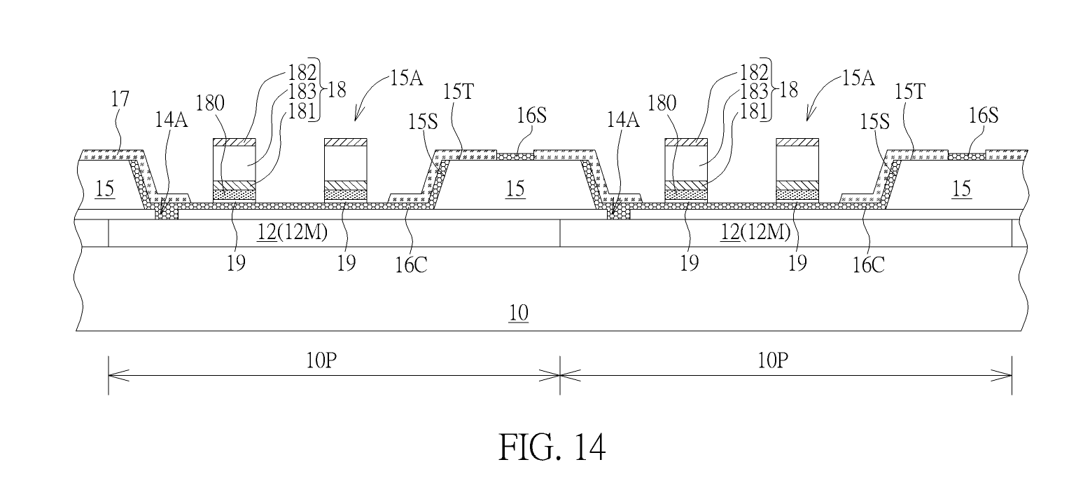

As shown in FIG. 14, at least one LED device 18 is formed on each first connection electrode 16C. In this embodiment, there are two LED devices 18 in each sub-pixel region 10P, but not limited thereto. The number and arrangement density may be modified based on the brightness requirement, the dimension specification of the sub-pixel region 10P and the dimension specification of the LED device 18. For example, there may be only one LED device 18 in each sub-pixel region 10P or more than two LED devices 18 in each sub-pixel region 10P. Each LED device 18 includes a first electrode (bottom electrode) 181, a second electrode (top electrode) 182 and a light emitting layer 183 interposed between the first electrode 181 and the second electrode 182, and each first electrode 181 is disposed on and electrically connected to the corresponding first connection electrode 16C. In this embodiment, the first electrode 181 is an anode, and the second electrode 182 is a cathode, but not limited thereto. The light emitting layer 183 is an inorganic light emitting layer, which can radiate light when driven by the voltage difference between the first electrode 181 and the second electrode 182. In this embodiment, the LED device 18 is fabricated in advance, and then mounted on and electrically connected to the first connection electrode 16C. Specifically, the first electrode 181, the light emitting layer 183 and the second electrode 182 are not sequentially formed on the first connection electrode 16C by thin film processes. For example, each LED device 18 may be picked up and placed on the corresponding first connection electrode 16C by a micro mechanical apparatus, and a conductive adhesive material 180 e.g. indium (In) may be used to weld the first LED device 18 on the welding layer 19. The first electrode 181 is therefore electrically connected to the first connection electrode 16C through the conductive adhesive material 180 and the welding layer 19. The conductive adhesive material 180 and the welding layer 19 may be formed by the same material or different materials. In another embodiment, the LED device 18 may be directly or indirectly mounted on the first connection electrode 16C in another manner.

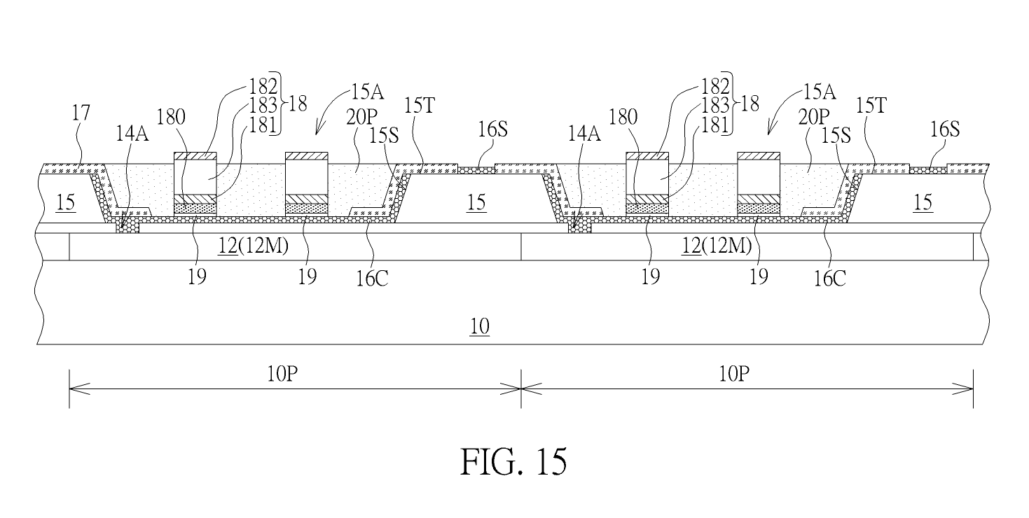

As shown in FIG. 15, a dielectric pattern 20P is formed in each cavity 15A. The dielectric pattern 20P surrounds the sidewall of the corresponding LED device 18, and exposes the second electrode 182 of the LED device 18 as well as the signal line 16S. The material of the dielectric pattern 20P may include inorganic material, organic material or organic/inorganic hybrid material. In this embodiment, the dielectric patterns 20P may be formed by an inkjet printing process, but not limited thereto. The top surface of the dielectric pattern 20P and the second electrode 182 are preferably located at the same horizontal level approximately or the height gap between the top surface of the dielectric pattern 20P and the second electrode 182 is as small as possible. The sidewall of the LED device 18 is surrounded by the dielectric pattern 20P, and thus the LED device 18 is well protected. In addition, the dielectric pattern 20P has light diffuse effect, which can increase light uniformity.

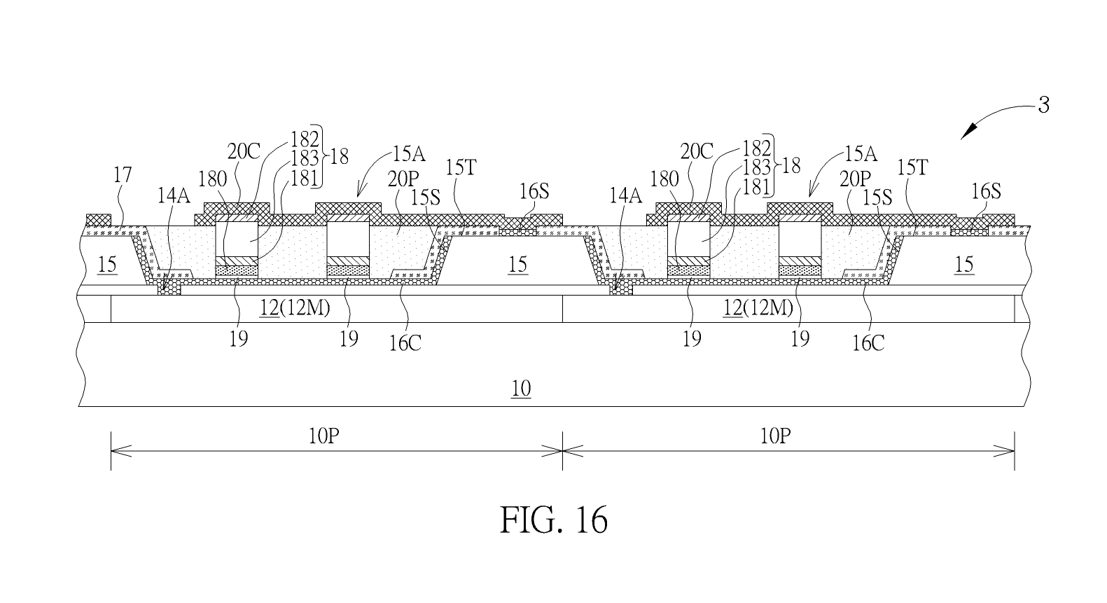

As shown in FIG. 16, a second connection electrode 22C is formed on each dielectric pattern 20P. Each second connection electrode 22C is extended to the patterned bank 15 to electrically connecting the second electrode 182 of the LED device 18 exposed by the corresponding dielectric pattern 20P and the corresponding signal line 16S to fabricate an LED display panel 3 of this embodiment. The second connection electrode 22C may be a single-layered electrode structure such as a non-transparent connection electrode (e.g. metal electrode) or a transparent connection electrode (e.g. indium tin oxide (ITO) electrode). Alternatively, the second connection electrode 22C may be a multi-layered electrode structure such as a stacking structure of a non-transparent connection electrode (e.g. metal electrode) and a transparent connection electrode (e.g. ITO electrode). The second connection electrodes 22C may be formed on the dielectric patterns 20P by thin film deposition process, an inkjet printing process, a screen printing process or other suitable processes. Since the top surface of the dielectric pattern 20P and the second electrode 182 are disposed at the same horizontal level approximately or the height gap between the top surface of the dielectric pattern 20P and the second electrode 182 is small, the line broken risk of the second connection electrode 22C due to large height gap is reduced, and thus the yield and reliability of the LED display device 3 is increased.

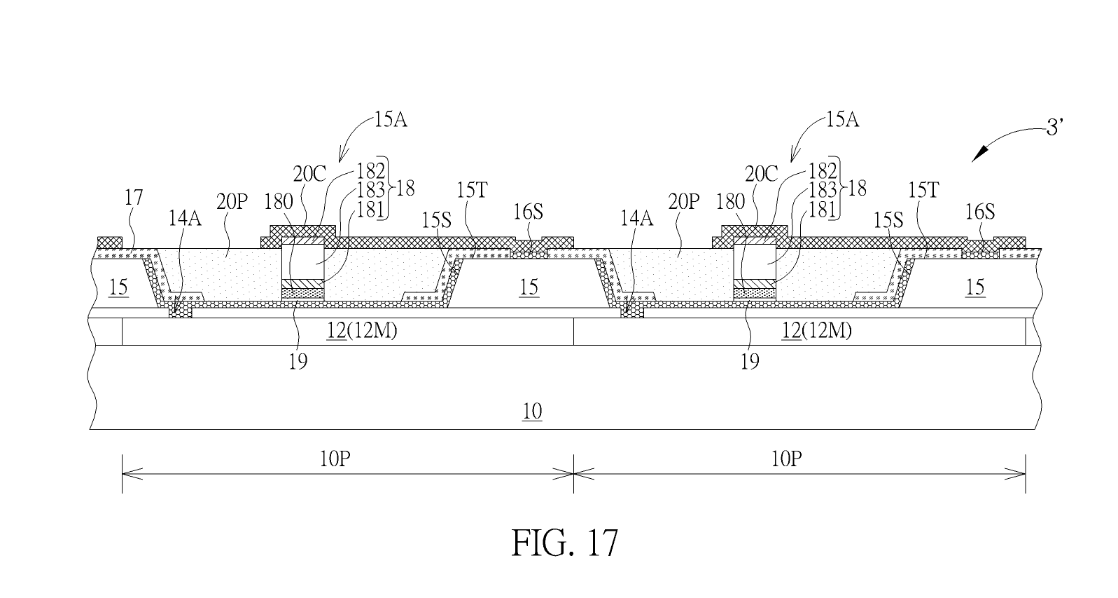

Refer to FIG. 17. FIG. 17 is a schematic diagram illustrating an LED display panel according to an alternative embodiment of the third embodiment of the present invention. As shown in FIG. 17, different from the third embodiment, in the LED display panel 3′ of this alternative embodiment, only one LED device 18 is disposed in each sub-pixel region 10P. By virtue of the light diffuse effect provided by the dielectric pattern 20P, the light uniformity of the LED display panel 3′ is enhanced.

In conclusion, according to the method of fabricating LED display panel of the present invention, the LED devices are first formed on the substrate, and then the dielectric patterns are subsequently formed to surround the sidewalls of the LED devices. Consequently, the LED devices are well protected by the dielectric patterns. In addition, since the top surface of the dielectric pattern and the second electrode of the LED device are disposed at the same horizontal level approximately or the height gap between the top surface of the dielectric pattern and the second electrode is small, the line broken risk of the second connection electrode is reduced. Moreover, the dielectric pattern has light diffuse effect, which can effectively increase light uniformity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting diode (LED) display panel, comprising:
a substrate, having a plurality of sub-pixel regions:
a plurality of driving devices, disposed on the substrate, wherein at least one of the driving devices is disposed in each of the sub-pixel regions:
an insulating layer, disposed on the substrate and covering the driving devices, wherein the insulating layer has a plurality of openings partially exposing the driving devices respectively;
a plurality of first connection electrodes, disposed on the insulating layer, wherein the first connection electrodes are electrically connected to the driving devices through the openings respectively;
a plurality of LED devices, disposed on the substrate, wherein at least one of the LED devices is disposed in each of the sub-pixel regions, each of the LED devices comprises a first electrode, a second electrode and a light emitting layer interposed between the first electrode and the second electrode, and the first electrodes are disposed on and electrically connected to the first connection electrodes respectively;
a plurality of dielectric patterns, disposed on the first connection electrodes respectively, wherein each of the dielectric patterns surrounds a sidewall of the corresponding LED device and exposes the second electrode of the corresponding LED device;
a plurality of signal lines, disposed on the substrate, wherein each of the signal lines is disposed on one side of the corresponding sub-pixel regions; and
a plurality of second connection electrodes, disposed on the dielectric patterns respectively, wherein the second connection electrodes are disposed in the sub-pixel regions respectively, and each of the second connection electrodes is electrically connected to the second electrode of the LED device exposed by the corresponding dielectric pattern and the corresponding signal line.

2. The LED display panel of claim 1, further comprising a plurality of conductive adhesive materials, wherein each of the conductive adhesive materials is disposed between the first electrode of the corresponding LED device and the corresponding first connection electrode, and configured to electrically connect the first electrode of the LED device and the first connection electrode.

3. The LED display panel of claim 1, wherein the signal lines are disposed on the insulating layer, and the dielectric patterns expose the signal lines.

4. The LED display panel of claim 1, wherein the signal lines are disposed on the dielectric patterns.

5. The LED display panel of claim 1, further comprising a plurality of reflection patterns, wherein each of the dielectric patterns has an inclined sidewall, and each of the reflection patterns is disposed on the inclined sidewall of the corresponding dielectric pattern.

6. The LED display panel of claim 1, further comprising a patterned bank, disposed on the insulating layer, wherein the patterned bank has a plurality of cavities defining the sub-pixel regions, and the dielectric pattern, the first connection electrode and the at least one LED device disposed in each of the sub-pixel regions is disposed in the corresponding cavity of the patterned bank.

7. The LED display panel of claim 6, wherein the signal lines are disposed on the patterned bank, and each of the second connection electrodes extends to the patterned bank and electrically connects the corresponding signal line.

8. A method of fabricating light emitting diode (LED) display panel, comprising:
providing a substrate having a plurality of sub-pixel regions:
forming a plurality of driving devices on the substrate, wherein at least one of the driving devices is disposed in each of the sub-pixel regions:
forming an insulating layer on the substrate and the driving devices, wherein the insulating layer has a plurality of openings partially exposing the driving devices respectively;
forming a plurality of first connection electrodes on the insulating layer and in the sub-pixel regions respectively, wherein the first connection electrodes are electrically connected to the driving devices through the openings respectively;
forming at least one LED device and a dielectric pattern on each of the first connection electrodes, wherein each of the LED devices comprises a first electrode, a second electrode and a light emitting layer interposed between the first electrode and the second electrode, and each of the first electrodes is disposed on and electrically connected to the corresponding first connection electrode, and each of the dielectric patterns surrounds a sidewall of the corresponding LED device and exposes the second electrode of the corresponding LED device;
forming a plurality of signal lines on the substrate, wherein each of the signal lines is disposed on one side of the corresponding sub-pixel regions; and
forming a plurality of second connection electrodes on the dielectric patterns respectively, wherein each of the second connection electrodes is electrically connected to the second electrode of the LED device exposed by the corresponding dielectric pattern and the corresponding signal line.

9. The method of fabricating LED display panel of claim 8, wherein steps of forming the at least one LED device and the dielectric pattern in each of the first connection electrodes comprise:
forming the at least one LED device on each of the first connection electrodes;
forming a dielectric material layer covering the first connection electrodes and the LED devices, wherein the dielectric material layer surrounds a sidewall of each of the LED devices and the second electrode of each of the LED devices; and
patterning the dielectric material layer to form the dielectric pattern on each of the first connection electrode and to expose the second electrode of each of the LED devices.

10. The method of fabricating LED display panel of claim 8, wherein the signal lines are disposed on the insulating layer, and the dielectric patterns expose the signal lines.

11. The method of fabricating LED display panel of claim 8, wherein the signal lines are disposed on the dielectric patterns.

12. The method of fabricating LED display panel of claim 8, wherein each of the dielectric patterns has an inclined sidewall.

13. The method of fabricating LED display panel of claim 12, further comprising forming a reflection pattern on the inclined sidewall of the corresponding dielectric pattern.

14. The method of fabricating LED display panel of claim 8, further comprising a patterned bank on the insulating layer prior to forming the first connection electrodes, wherein the patterned bank surrounds each of the sub-pixel regions, and the patterned bank has a plurality of cavities partially exposing the sub-pixel regions respectively.

15. The method of fabricating LED display panel of claim 14, wherein steps of forming the first connection electrodes on the insulating layer and forming the at least one LED device and the dielectric pattern on each of the first connection electrodes comprise:
forming the first connection electrodes in the cavities subsequent to forming the patterned bank;
forming the at least one LED device on each of the first connection electrodes; and
forming the dielectric pattern on each of the first connection electrodes to surround the sidewall of the at least one LED device and to expose the second electrode.

16. The method of fabricating LED display panel of claim 14, wherein the signal lines are disposed on the patterned bank, and each of the second connection electrodes extends to the patterned bank and electrically connects the corresponding signal line.
